(19) United States
(12) Patent Application Publication
(10) Pub. No.: US 2026/0353758 A1
(43) Pub. Date: Nov. 5, 2026

(54) COMPOUND SEMICONDUCTOR DEVICE AND METHOD FOR MANUFACTURING COMPOUND SEMICONDUCTOR DEVICE

(71) Applicant: FUJI ELECTRIC CO., LTD., Kawasaki-shi (JP)

(72) Inventors: Nao MIYAGI, Tokyo (JP); Katsunori UENO, Matsumoto-city (JP)

(73) Assignee: FUJI ELECTRIC CO., LTD., Kawasaki-shi (JP)

(21) Appl. No.: 19/569,697

(22) Filed: Mar. 17, 2026

(30) Foreign Application Priority Data
May 1, 2025 (JP) 2025-076241

(51) Int. Cl. H10D 64/68; H10D 30/01; H10D 30/66; H10D 62/832; H10D 62/85

(52) U.S. Cl. CPC H10D 64/685; H10D 30/0291; H10D 30/66; H10D 62/8325; H10D 62/8503; H10D 64/691

(57) ABSTRACT

Provided is a compound semiconductor device capable of suppressing a reduction in threshold voltage. The compound semiconductor device includes a compound semiconductor substrate and a vertical MOSFET provided on the compound semiconductor substrate. The vertical MOSFET has a gate insulating film provided on a first surface of the compound semiconductor substrate, a gate electrode provided on the first surface of the compound semiconductor substrate through the gate insulating film, an interlayer insulating film provided on the first surface of the compound semiconductor substrate and covering the gate electrode, and an N-type source region provided in the compound semiconductor substrate. The gate electrode has a stacked-layer structure containing a conductive layer and a hydrogen blocking layer containing a conductive material different from a conductive material of the conductive layer and blocking the diffusion of hydrogen. The gate electrode has an end part overlapping the source region through the gate insulating film.

### CROSS-REFERENCE TO RELATED APPLICATION

This application claims benefit of priority under 35 USC 119 based on Japanese Patent Application No. 2025-076241 filed on May 1, 2025, the entire contents of which are incorporated by reference herein.

### BACKGROUND OF THE INVENTION

### 1. Field of the Invention

The present disclosure relates to a compound semiconductor device and a method for manufacturing a compound semiconductor device.

### 2. Description of the Related Art

To solve a problem of a reduction over time of threshold voltage in a SiC semiconductor device, a technology is known in which barrier metal layers suppressing the diffusion of Al are interposed individually between a source electrode and an interlayer insulating film and between a gate pad and a gate electrode (see JP 5694119 B, for example).

Further, to prevent the diffusion of metal components constituting a gate electrode into a gate insulating film, a technology is known in which a lower layer of the gate electrode is constituted by a metal having a high melting point (see JP 2024-154505 A, for example).

### SUMMARY OF THE INVENTION

A compound semiconductor device capable of suppressing the reduction in threshold voltage has been demanded.

It is an object of the present disclosure to provide a compound semiconductor device capable of suppressing a reduction in threshold voltage and a method for manufacturing a compound semiconductor device.

### SOLUTION TO PROBLEM

To solve the above-described problem, a compound semiconductor device according to one aspect of the present disclosure includes: a compound semiconductor substrate; and a vertical MOSFET provided on the compound semiconductor substrate. The vertical MOSFET has a gate insulating film provided on a first surface of the compound semiconductor substrate, a gate electrode provided on the first surface of the compound semiconductor substrate through the gate insulating film, an interlayer insulating film provided on the first surface of the compound semiconductor substrate and covering the gate electrode, and an N-type source region provided in the compound semiconductor substrate. The gate electrode has a stacked-layer structure containing a conductive layer and a hydrogen blocking layer containing a conductive material different from a conductive material of the conductive layer and blocking the diffusion of hydrogen. The gate electrode has an end part overlapping the source region through the gate insulating film.

### BRIEF DESCRIPTION OF THE DRAWINGS

FIG. 1 is a cross-sectional view illustrating a configuration example of a GaN semiconductor device according to this embodiment 1;

FIG. 2 is a cross-sectional view illustrating a part of FIG. 1 in an enlarged manner;

FIGS. 3A and 3B are cross-sectional views illustrating a configuration example (two-layer structure) of the gate electrode according to this embodiment 1;

FIGS. 4A and 4B are cross-sectional views illustrating a configuration example (four-layer structure) of the gate electrode according to this embodiment 1;

FIG. 5 is a cross-sectional view illustrating a configuration example of a GaN semiconductor device according to this embodiment 2;

FIG. 6 is a cross-sectional view illustrating a configuration example of a GaN semiconductor device according to this embodiment 3;

FIG. 7A and 7B are cross-sectional views illustrating a method for manufacturing a vertical MOSFET according to this embodiment 4 in the order of steps;

FIG. 8A and 8B are cross-sectional views illustrating the method for manufacturing a vertical MOSFET according to this embodiment 4 in the order of steps; and

FIG. 9A and 9B are cross-sectional views illustrating the method for manufacturing a vertical MOSFET according to this embodiment 4 in the order of steps.

### DETAILED DESCRIPTION

Hereinafter, embodiments of the present disclosure (this embodiment) are described. In the description of the drawings below, the same or similar reference signs are attached to the same or similar portions. It should be noted that the drawings are schematic, and the relation between the thickness and the plane dimension, the thickness ratio of each device or each member, and the like are different from the actual relation, thickness ratio, and the like. Therefore, the specific thickness and dimension should be determined in consideration of the description below. It is a matter of course that the drawings also include portions different in mutual dimensional relations and ratios.

In the description below, the directions are sometimes described using words of an X-axis direction, a Y-axis direction, and a Z-axis direction. For example, the X-axis direction and the Y-axis direction are directions parallel to a front surface 10a of a GaN substrate 10 described later. The X-axis direction and the Y-axis direction each are also referred to as the horizontal direction.

The Z-axis direction is a direction perpendicularly intersecting the front surface 10a of the GaN substrate 10 and is also the thickness direction of the GaN substrate 10. The X-axis direction, the Y-axis direction, and the Z-axis direction are orthogonal to each other.

In the description below, the positive direction of the Z-axis is sometimes referred to as "upper" and the negative direction of the Z-axis is sometimes referred to as "lower”. However, the "upper" and the "lower" do not always mean the vertical direction relative to the ground. More specifically, the directions of "upper" and "lower" are not limited to the direction of gravity. "Upper" and "lower" are merely convenient expressions for specifying the relative positional relations of regions, layers, films, substrates, and the like, and do not limit the technical idea of the present disclosure. For example, it is a matter of course that, when the paper is rotated 180 degrees, "upper" becomes "lower" and "lower" become "upper".

In the description below, + and - attached to P and N indicating the conductivity type mean that semiconductor regions attached by + and - have a relatively higher or lower impurity concentration than that of semiconductor regions not attached by + and -, respectively. However, even when semiconductor regions are attached by the same P and P (or N and N), it does not mean that the impurity concentrations of the semiconductor regions are exactly the same.

### Embodiment 1

### Configuration Example

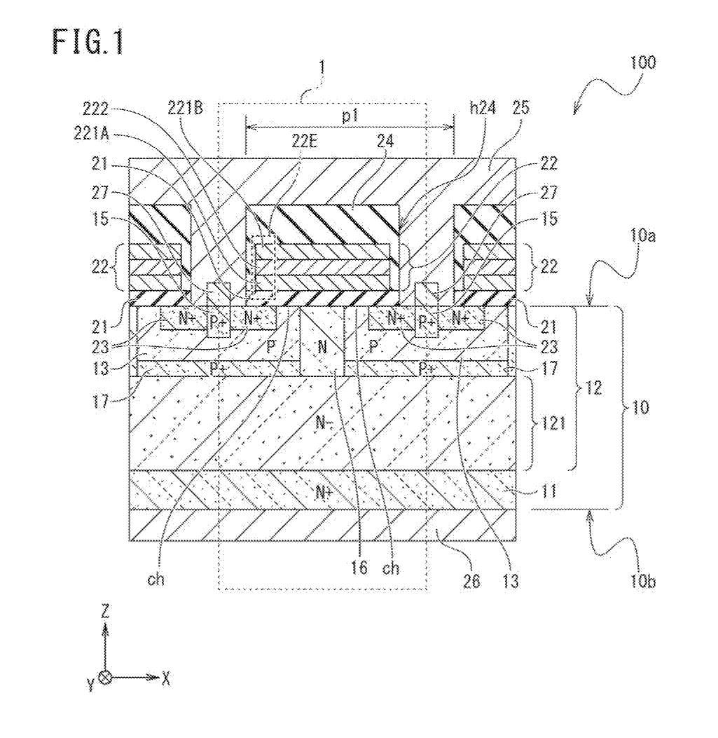

FIG. 1 is a cross-sectional view illustrating a configuration example of a GaN semiconductor device 100 (one example of the "compound semiconductor device" of the present disclosure) according to this embodiment 1. As illustrated in FIG. 1, the GaN semiconductor device 100 includes a gallium nitride substrate (one example of the "compound semiconductor" of the present disclosure; hereinafter, GaN substrate) 10 and a plurality of vertical MOSFETs (Metal Oxide Semiconductor Field Effect Transistor) 1 provided on the GaN substrate 10. The plurality of vertical MOSFETs 1 is repeatedly provided in one direction (e.g., X-axis direction). One vertical MOSFET 1 is a repeating unit structure, and the unit structures are arranged side by side in one direction.

The GaN substrate 10 has an N⁺-type GaN single crystal substrate 11 and a GaN layer 12 provided on the GaN single crystal substrate 11. The GaN single crystal substrate 11 is an N⁺-type c-plane GaN single crystal substrate, for example. An N-type impurity contained in the GaN single crystal substrate 11 is one or more of silicon (Si), oxygen (O), and germanium (Ge), for example. As one example, the GaN single crystal substrate 11 contains Si as the N-type impurity, and the impurity concentration of Si in the GaN single crystal substrate 11 is 5 × 10¹⁷ cm⁻³ or more.

The GaN single crystal substrate 11 may be a low-dislocation freestanding substrate having a dislocation density of less than 1 × 10⁷ cm⁻². Due to the fact that the GaN single crystal substrate 11 is a low-dislocation freestanding substrate, the dislocation density of the GaN layer 12 formed on the GaN single crystal substrate 11 is also low. The use of the low-dislocation freestanding substrate allows a reduction in leakage current in a large-area power device, even when the power device is formed on the GaN substrate 10. This allows a manufacturing device to manufacture the power device with a high non-defective rate. Further, ion-implanted impurities can be prevented from deeply diffusing along the dislocation in heat treatment.

The GaN layer 12 is a single crystal GaN layer epitaxially grown on one surface of the GaN single crystal substrate 11. The GaN layer 12 is provided with a drift region 121.

The GaN substrate 10 has the front surface 10a (one example of the "first surface" of the present disclosure) and a rear surface 10b positioned on the opposite side to the front surface 10a. The front surface of the GaN layer 12 is equivalent to the front surface 10a of the GaN substrate 10, and the rear surface of the GaN single crystal substrate 11 is equivalent to the rear surface 10b of the GaN substrate 10.

The vertical MOSFET 1 is a planar gate type (having a planar gate structure) and has P-type well regions 13 provided on the front surface 10a side of the GaN substrate 10, P⁺-type contact regions 15 positioned inside the well regions 13, N⁺-type source regions 23 positioned inside the well regions 13, an N-type JFET region 16 positioned outside the well regions 13, and P⁺-type shield regions 17 provided in the GaN layer 12. In the GaN layer 12, the regions excluding the well regions 13, the contact regions 15, the source regions 23, and the JFET region 16 are the drift region 121. The drift region 121 is in contact with the N⁺-type GaN single crystal substrate 11. The drift region 121 contains, for example, Si as the N-type impurity at a concentration of 1 × 10¹⁵ cm⁻³ or more and 1 × 10¹⁷ cm⁻³ or less (1 × 10¹⁶ cm⁻³ as one example). The drift region 121 has a thickness of 5 μm or more and 20 μm or less (10 μm as one example), for example.

The vertical MOSFET 1 includes a gate insulating film 21 provided on the front surface 10a side of the GaN substrate 10, a gate electrode 22 provided on the gate insulating film 21, an interlayer insulating film 24 provided on the front surface 10a side of the GaN substrate 10 and covering the gate electrode 22, a source electrode 25 provided on the front surface 10a side of the GaN substrate 10 and in contact with the N⁺-type source regions 23, a drain electrode 26 provided on the rear surface 10b side of the GaN substrate 10 and in contact with the N⁺-type GaN single crystal substrate 11, and contact electrodes 27 provided on the front surface 10a side of the GaN substrate 10 and in contact with the P⁺-type contact regions 15.

The well regions 13 are, for example, P-type layers formed by ion implantation of a P-type impurity, such as Mg, to the front surface 10a side of the GaN substrate 10 and activation of the P-type impurity by heat treatment. The well regions 13 contain, for example, Mg as the P-type impurity at a concentration of 1 × 10¹ ⁶ cm⁻³ or more and 1 × 10¹ ⁸ cm⁻³ or less (1 × 10¹ ⁷ cm⁻³ as one example). The well regions 13 face the front surface 10a of the GaN substrate 10 and are in contact with the gate insulating film 21.

The contact regions 15 are, for example, P⁺-type layers formed by ion implantation of the P-type impurity, such as Mg, to the front surface 10a side of the GaN substrate 10 and activation of the P-type impurity by heat treatment. The contact regions 15 contain Mg as the P-type impurity at a concentration of 1 × 10¹ ⁸ cm⁻³ or more and 1 × 10²⁰ cm⁻³ or less (1 × 10¹ ⁹ cm⁻³ as one example). The contact regions 15 face the front surface 10a of the GaN substrate 10. The contact regions 15 are positioned inside the well regions 13 and are in contact with the well regions 13. The contact regions 15 are also in contact with the source regions 23.

The well regions 13 are connected to the source electrode 25 through the contact regions 15. This fixes the potential of the well regions 13 to the potential of the source electrode 25 (e.g., reference potential, such as ground potential (GND)).

The JFET region 16 is a region sandwiched from both sides by the P-type well regions 13, which form a pair, adjacent to each other in the horizontal direction in the GaN layer 12. The JFET region 16 contains, for example, Si as the N-type impurity at a concentration of 1 × 10¹ ⁶ cm⁻³ or more and 1 × 10¹⁸ cm⁻³ or less (1 × 10¹ ⁷ cm⁻³ as one example).

The P⁺-type shield regions 17 are positioned directly under the P-type well regions 13 and in contact with the well regions 13. A depletion layer formed between the P⁺-type shield regions 17 and the N⁻-type GaN layer 12 can increase a gate-off breakdown voltage. The P⁺-type shield regions 17 contain, for example, Mg as the P-type impurity at a concentration of 1 × 10¹⁸ cm⁻³ or more and 1 × 10²⁰ cm⁻³ or less (1 × 10¹ ⁹ cm⁻³ as one example).

The source regions 23 are N⁺-type layers formed by ion implantation of the N-type impurity, such as Si or O, to the front surface 10a side of the GaN substrate 10 and activation of the N-type impurity by heat treatment. The source regions 23 contain, for example, Si as the N-type impurity at a concentration of 1 × 10¹⁹ cm⁻³ or more and 1 × 10²⁰ cm⁻³ or less (1 × 10²⁰ cm⁻³ as one example). The source regions 23 are provided in the well regions 13 under both sides of the gate electrode 22 and face the front surface 10a of the GaN substrate 10. The source regions 23 are positioned inside the well regions 13 and are in contact with the well regions 13.

The gate insulating film 21 contains, for example, one or more layers of silicon oxide (SiO₂), aluminum oxide (Al₂O₃), aluminum silicate (AlSiO₂), zirconium oxide (ZrO₂), and hafnium oxide (HfO₂). The gate insulating film 21 may be a single-layer film containing any one of the layers above or may be a stacked-layer film containing one or more of the layers above. The gate insulating film 21 has a thickness per layer of 50 nm or more and 200 nm or less, for example. As one example, the gate insulating film 21 is a SiO₂ film and has a thickness of 100 nm.

The gate electrode 22 is adjacent to a region where a channel is formed (hereinafter "channel region") through the gate insulating film 21. The gate electrode 22 is opposed to the well regions 13 and the source regions 23 through the gate insulating film 21.

The gate electrode 22 has a stacked-layer structure containing a conductive layer and a hydrogen blocking layer containing a conductive material different from a conductive material of the conductive layer and blocking the diffusion of hydrogen. For example, the gate electrode 22 has a first conductive layer 221A serving as a lower layer, a second conductive layer 221B serving as an upper layer, and a hydrogen blocking layer 222 positioned between the first conductive layer 221A and the second conductive layer 221B. In other words, the first conductive layer 221A is interposed between the gate insulating film 21 and the hydrogen blocking layer 222, and the second conductive layer 221B is interposed between the hydrogen blocking layer 222 and the interlayer insulating film 24. On the gate insulating film 21, the first conductive layer 221A, the hydrogen blocking layer 222, and the second conductive layer 221B are stacked in this order.

The first conductive layer 221A and the second conductive layer 221B each contain a conductive material, such as nickel (Ni), aluminum (Al), tungsten (W), titanium nitride (TiN), or polysilicon doped with impurities (doped-poly Si). The first conductive layer 221A and the second conductive layer 221B may contain the same type of conductive material or may contain different types of conductive materials. The first conductive layer 221A and the second conductive layer 221B each have a thickness of 10 nm or more and 500 nm or less (50 nm as one example), for example. The first conductive layer 221A and the second conductive layer 221B may have the same thickness or may have different thicknesses.

The hydrogen blocking layer 222 contains one of simple metals of titanium (Ti), zirconium (Zr), palladium (Pd), and magnesium (Mg) or a Ti compound containing titanium (Ti) as the main component. The hydrogen blocking layer 222 has a thickness of 10 nm or more and 200 nm or less. As one example, the hydrogen blocking layer 222 contains Ti and has a thickness of 100 nm.

The interlayer insulating film 24 is provided on the front surface 10a side of the GaN substrate 10 and covers the upper surface and the side surfaces of the gate electrode 22. The interlayer insulating film 24 is, for example, a SiO₂ film. This SiO₂ film may be, for example, a plasma TEOS film formed by a plasma CVD method using TEOS (tetraethoxysilane) as a raw material or an insulating film formed by a CVD method using monosilane as a raw material. Alternatively, this SiO₂ film may be a silicon glass film containing boron and phosphorus (BPSG film) or a silicon glass film containing phosphorus (PSG film). The interlayer insulating film 24 has a thickness of 500 nm or more and 2000 nm or less (1000 nm as one example), for example. The interlayer insulating film 24 is provided with a contact hole h24 with the N⁺-type source regions 23 and the P⁺-type contact regions 15 as the bottom surface.

The contact electrodes 27 are provided in the contact hole h24 and are connected to the contact regions 15 in an ohmic manner. Further, in the contact hole h24, the contact electrodes 27 are covered with the source electrode 25 and are in contact with the source electrode 25. The contact electrodes 27 may contain one or more of nickel (Ni), palladium (Pd), titanium nitride (TiN), titanium (Ti), or aluminum (Al). For example, the contact electrodes 27 contain Ni. The thickness of the contact electrodes 27 may be larger than 0 nm and smaller than the depth of the contact hole h24, and is 50 nm as one example.

The source electrode 25 is provided to cover the gate electrode 22 through the interlayer insulating film 24 and bury the contact hole h24. The source electrode 25 is connected to the N⁺-type source regions 23 in an ohmic manner. The source electrode 25 is connected to the P⁺-type contact regions 15 in an ohmic manner through the contact electrodes 27. The drain electrode 26 is connected to the rear surface 10b of the GaN substrate 10 (i.e., rear surface of the N⁺-type GaN single-crystal substrate 11) in an ohmic manner.

The source electrode 25 and the drain electrode 26 contain Al or Al-Si alloys, Ni, Ni alloys, Ti-Al alloys, Ni-gold (Au) alloys, and the like. The source electrode 25 may also have a barrier metal layer between the source electrode 25 and the source region 23. The drain electrode 26 may have a barrier metal layer between the drain electrode 26 and the N⁺-type GaN single crystal substrate 11. The barrier metal layer may contain Ti (titanium) or a stack of Ti and TiN (titanium nitride). For the barrier metal layer, the same material as that of the hydrogen blocking layer 222 may be used.

More specifically, the source electrode 25 and the drain electrode 26 may be a stack of a Ti layer and an Al layer or a stack of a Ti layer and an Al-Si alloy layer. The source electrode 25 and the drain electrode 26 may contain materials different from each other and may have different stacked-layer structures. As one example, the source electrode 25 has a Ti/Al stacked-layer structure. In the source electrode 25, the thickness of Ti is 100 nm and the thickness of Al is 5000 nm. Between the source regions 23 and Al, Ti is interposed. The drain electrode 26 has a Ti/Al stacked-layer structure. In the drain electrode 26, the thickness of Ti is 100 nm and the thickness of Al is 200 nm. Between the rear surface 10b of the GaN substrate 10 and Al, Ti is interposed. A configuration may be acceptable in which an alloy layer of Ti and Al is provided between the Ti layer and the Al layer.

The cell pitch (i.e., arrangement pitch) of the vertical MOSFETs 1 is not particularly limited, and is 5 μm or more and 10 μm or less as one example and is 6 μm as one example.

### Mechanism of Vth reduction suppression

1. Presence of hydrogen blocking layer
For the formation of an interlayer insulating film, a raw material gas containing hydrogen atoms is used, and therefore hydrogen (H) is mixed into the interlayer insulating film in the film formation. The interlayer insulating film after the film formation is subjected to heat treatment for the purpose of firing (densification) or the like. In this heat treatment, the hydrogen in the interlayer insulating film partially diffuses to a gate electrode side. When the hydrogen passes through the gate electrode and a gate insulating film positioned under the gate electrode and reaches the interface between the gate insulating film and a P-type well region, the hydrogen reduces GaOx thinly present in this interface, and the hydrogen partially becomes a positive fixed charge. This positive fixed charge is considered to contribute to the reduction in threshold voltage (Vth). In the P-type well region, ion-implanted Mg or the like contribute as an acceptor. When the hydrogen reaches the P-type well region, the hydrogen bonds with the Mg (forms a Mg-H bond) and inactivates the Mg (electrical activity is lost). It is considered that the inactivated Mg is increased in resistance, causing a further reduction in Vth and an increase in resistance of a channel region.

Herein, in the vertical MOSFET 1 illustrated in FIG. 1, the presence of the hydrogen blocking layer 222 in the gate electrode 22 blocks the diffusion of the hydrogen (H) from the hydrogen blocking layer 222 to the gate insulating film 21 side. For example, the hydrogen diffused from the interlayer insulating film 24 into the gate electrode 22 is absorbed or blocked by the hydrogen blocking layer 222 containing Ti or the like to prevent the diffusion of the hydrogen to the gate insulating film 21 side. This can prevent the mixing of the hydrogen into the interface between the gate insulating film B and the P-type well regions 13 and to the well regions 13, and therefore can suppress the generation of the positive fixed charge and the inactivation of Mg described above. This can suppress the reduction in Vth. Further, the hydrogen blocking layer 222 is sandwiched between the first conductive layer 221A and the second conductive layer 221B, and therefore the hydrogen blocking layer 222 can be securely left without losing the hydrogen blocking capability during manufacturing.

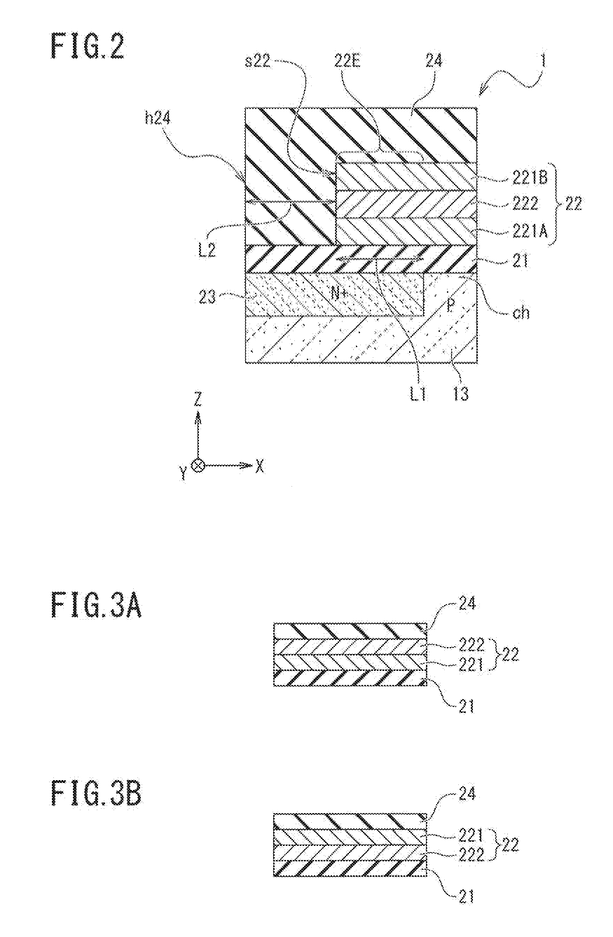

2. Specification of length L1
FIG. 2 is a cross-sectional view illustrating a part of FIG. 1 in an enlarged manner and specifically is a cross-sectional view illustrating an end part 22E of the gate electrode 22 and its surrounding part in an enlarged manner. In this embodiment 1, it is preferable to specify the length (dimension) of a region where the end part 22E of the gate electrode 22 and the source region 23 overlap each other to prevent the mixing of hydrogen into the channel region.

As illustrated in FIG. 2, the end part 22E of the gate electrode 22 overlaps the N⁺-type source region 23 through the gate insulating film 21. When the length in the gate length direction (e.g., X-axis direction) of the region where the end part 22E and the source region 23 overlap each other is set as L1, the length L1 is preferably equal to or larger than the thickness of the gate insulating film 21 (e.g., 100 nm or more) and 0.6 μm or less. When the length L1 is small, hydrogen (H) is likely to enter, from the side direction, a channel region ch from the interlayer insulating film 24 through the gate insulating film 21. However, when the length L1 is set to a thickness equal to or larger than at least the thickness of the gate insulating film 21, the entrance of H from the side can be prevented. For the length L1, an upper limit is preferably set. For example, by setting the length L1 to 0.6 μm or less, an excessive increase in cell pitch p1 can be suppressed and an increase in channel resistance can be suppressed.

3. Specification of width L2
In this embodiment 1, the width (dimension) of the sidewall of the interlayer insulating film 24 is preferably specified to prevent the mixing of hydrogen into the channel region ch. As illustrated in FIG. 2, when a portion covering a side surface s22 of the gate electrode 22 of the interlayer insulating film 24 is set as the sidewall, the width L2 of this sidewall is preferably equal to or larger than the thickness of the gate insulating film 21 (e.g., 100 nm or more) and 0.5 μm or less. The width L2 of this sidewall may be rephrased as the distance from the side surface s22 of the gate electrode 22 to the contact hole h24.

The smaller the width L2 of the sidewall, the smaller the absolute amount of H contained in the sidewall, which is advantageous in preventing the mixing of H from the sidewall into the channel region ch. However, when the width L2 of the sidewall decreases, the gate electrode 22 and the source electrode 25 come close to each other, increasing a possibility of a short circuit between both the electrodes. To reduce this possibility, the width L2 of the sidewall preferably has a thickness equal to or larger than at least the thickness of the gate insulating film 21. For the width L2, an upper limit is preferably set. For example, by setting the width L2 to 0.5 μm or less, the excessive increase in cell pitch p1 can be suppressed and the increase in channel resistance can be suppressed.

### Effects of embodiment 1

As described above, the GaN semiconductor device 100 according to this embodiment 1 includes the GaN substrate 10 and the vertical MOSFET 1 provided on the GaN substrate 10. The vertical MOSFET 1 has the gate insulating film 21 provided on the front surface 10a side of the GaN substrate 10, the gate electrode 22 provided on the front surface 10a side of the GaN substrate 10 through the gate insulating film 21, the interlayer insulating film 24 provided on the front surface 10a side of the GaN substrate 10 and covering the gate electrode 22, and the N-type source region 23 provided in the GaN substrate 10. The gate electrode 22 has the stacked-layer structure containing the conductive layers 221 (e.g., first conductive layer 221A, second conductive layer 221B) and the hydrogen blocking layer 222 containing a conductive material different from a conductive material of the conductive layer 221 and blocking the diffusion of hydrogen. The end part 22E of the gate electrode 22 overlaps the source region 23 through the gate insulating film 21.

This can prevent the hydrogen contained in the interlayer insulating film 24 from diffusing into the interface between the gate insulating film 21 and the GaN substrate 10. This can prevent the hydrogen from reducing the oxide film (e.g., GaOx) thinly present in this interface and prevent the hydrogen from partially becoming the positive fixed charge. Further, the source region 23 is covered with the end part 22E of the gate electrode 22, and therefore the hydrogen can also be prevented from diffusing from the end part 22E of the gate electrode 22 into the channel region ch through the source region 23. This can prevent the acceptor (e.g., Mg) present in the channel region ch from being inactivated by bonding of the acceptor with the hydrogen.

Thus, the increase in positive fixed charge can be prevented in the interface between the gate insulating film 21 and the GaN substrate 10, and the inactivation of the acceptor can be prevented in the channel region ch, and therefore the reduction in threshold voltage (Vth) can be suppressed. Further, the inactivation of the acceptor can be prevented, and, as a result, the increase in resistance of the channel region ch can be prevented, and therefore changes in Vth can be suppressed. The acceptor of the channel region ch is activated, and the electrical characteristics are improved.

### Modifications

The above-described embodiment 1 describes that the gate electrode 22 contains the three layers of the first conductive layer 221A, the hydrogen blocking layer 222, and the second conductive layer 221B. However, in this embodiment 1, the configuration of the gate electrode 22 is not limited to the three-layer structure illustrated in FIGS. 1 and 2. In this embodiment, the stacking order and the number of stacked layers of the conductive layer 221 and the hydrogen blocking layer 222 constituting the gate electrode 22 may be optionally set. For example, the gate electrode 22 may be a two-layer structure containing one layer of each of the conductive layer 221 and the hydrogen blocking layer 222 or a stacked-layer structure in which the conductive layers 221 and the hydrogen blocking layers 222 are alternately stacked several times.

FIGS. 3A and 3B are cross-sectional views illustrating a configuration example (two-layer structure) of the gate electrode 22 according to this embodiment 1. As illustrated in FIG. 3A, the gate electrode 22 may have a two-layer structure in which the conductive layer 221 and the hydrogen blocking layer 222 are stacked in this order on the gate insulating film 21. As illustrated in FIG. 3B, the gate electrode 22 may also have a two-layer structure in which the hydrogen blocking layer 222 and the conductive layers 221 are stacked in this order on the gate insulating film 21. In both the aspects of FIGS. 3A and 3B, the diffusion of hydrogen from the interlayer insulating film 24 into the gate insulating film 21 can be prevented.

In the aspect of FIG. 3B, the conductive layer 221 is stacked on the hydrogen blocking layer 222, and therefore the hydrogen blocking layer 222 is covered with the conductive layer 221 in the formation of the interlayer insulating film 24. This can prevent the hydrogen blocking layer 222 from being exposed to a gas atmosphere containing an oxidation seed and can prevent the hydrogen blocking layer 222 from being oxidized in the formation of the interlayer insulating film 24, for example. In the aspect of FIG. 3A, the conductive layer 221 is interposed between the gate insulating film 21 and the hydrogen blocking layer 222, preventing the contact between the gate insulating film 21 and the hydrogen blocking layer 222. This can prevent the occurrence of a chemical reaction (e.g., redox reaction) between the gate insulating film 21 and the hydrogen blocking layer 222 in heat treatment after the formation of the interlayer insulating film 24, for example, and can prevent a deterioration of the characteristics of the gate insulating film 21.

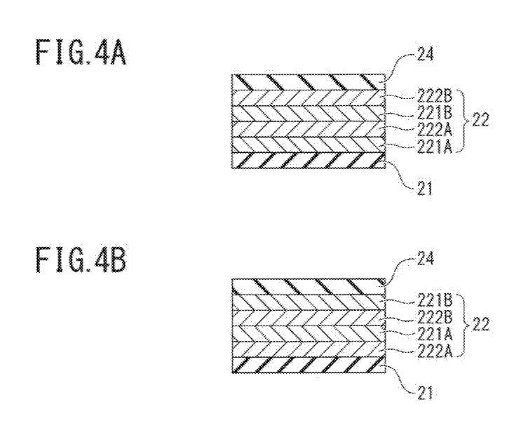

FIGS. 4A and 4B are cross-sectional views illustrating a configuration example (four-layer structure) of the gate electrode 22 according to this embodiment 1. As illustrated in FIG. 4A, the gate electrode 22 may have a four-layer structure in which the first conductive layer 221A, a first hydrogen blocking layer 222A, the second conductive layer 221B, and a second hydrogen blocking layer 222B are stacked in this order on the gate insulating film 21. As illustrated in FIG. 4B, the gate electrode 22 may have a four-layer structure in which the first hydrogen blocking layer 222A, the first conductive layer 221A, the second hydrogen blocking layer 222B, and the second conductive layer 221B are stacked in this order on the gate insulating film 21.

In both the aspects of FIGS. 4A and 4B, the conductive layer 221 (e.g., first conductive layer 221A or second conductive layer 221B) is interposed between the first hydrogen blocking layer 222A and the second hydrogen blocking layer 222B. The conductive layers 221 have a thickness per layer (e.g., the thickness of each of the first conductive layer 221A and the second conductive layer 221B) of 10 nm or more and 200 nm or less. The hydrogen blocking layers 222 have a thickness per layer (e.g., the thickness of each of the first hydrogen blocking layer 222A and the second hydrogen blocking layer 222B) of 10 nm or more and 200 nm or less.

In the aspects illustrated in FIGS. 4A and 4B, the first hydrogen blocking layer 222A and the second hydrogen blocking layer 222B can prevent the diffusion of hydrogen from the interlayer insulating film 24 into the gate insulating film 21. Although not illustrated, even a stacked-layer structure of five or more layers in which the conductive layers 221 and the hydrogen blocking layers 222 are alternately stacked exhibits the same effects.

### Embodiment 2

The embodiment 1 describes that the vertical MOSFET 1 has the planar gate structure. However, a vertical MOSFET according to this embodiment is not limited thereto and may be a trench-gate vertical MOSFET.

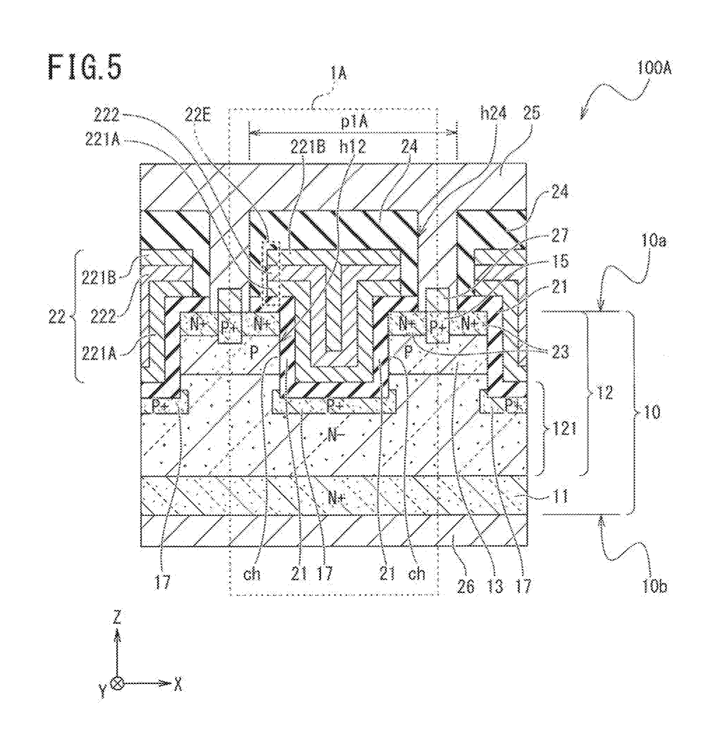

FIG. 5 is a cross-sectional view illustrating a configuration example of a GaN semiconductor device 100A according to this embodiment 2. As illustrated in FIG. 5, the GaN semiconductor device 100A has a GaN substrate 10 and a plurality of vertical MOSFETs 1A provided on the GaN substrate 10. The plurality of vertical MOSFETs 1A is repeatedly provided in one direction (e.g., X-axis direction). One vertical MOSFET 1A is a repeating unit structure, and the unit structures are arranged side by side in one direction. The vertical MOSFET 1A has a trench gate structure. More specifically, a trench h12 is provided on the front surface 10a side of the GaN substrate 10 with the N⁻-type GaN layer 12 as the bottom surface. In this trench h12, the gate electrode 22 is arranged through the gate insulating film 21. As illustrated in FIG. 5, a P⁺-type shield region 17 may be provided under the bottom surface of the trench h12. In this case, the bottom surface of the trench h12 serves as the P⁺-type shield region 17.

For example, the gate electrode 22 has a three-layer structure in which the first conductive layer 221A, the hydrogen blocking layer 222, and the second conductive layer 221B are stacked in this order from the gate insulating film 21 side. All the three layers are arranged in the trench h12. All the three layers are extended from within the trench h12 onto the front surface 10a of the GaN substrate 10 and onto a peripheral region of the trench h12. Also in this example, the upper surface and the side surfaces of the gate electrode 22 are covered with the interlayer insulating film 24. A cell pitch p1A of the vertical MOSFETs 1A is not particularly limited, and is 3 μm or more and 8 μm or less as one example and is 4 μm as one example.

Also in the vertical MOSFET 1A according to the embodiment 2, the gate electrode 22 has the stacked-layer structure containing the conductive layer 221 and the hydrogen blocking layer 222 as with the vertical MOSFET 1 according to the embodiment 1. The end part 22E of the gate electrode 22 overlaps the source region 23 through the gate insulating film 21. This can suppress the reduction in Vth. More specifically, in the trench gate vertical MOSFET 1A, an upper part of the channel region ch is covered with the N⁺-type source region 23, and therefore the mixing of hydrogen from above is less likely to occur. In this structure, the hydrogen blocking layer 222 is provided in the trench h12, which can prevent hydrogen from mixing into the channel region ch through the gate electrode 22 in the trench h12.

Also in the embodiment 2, it is preferable to specify the length of the region where the end part 22E of the gate electrode 22 and the source region 23 overlap each other as with the length L1 illustrated in FIG. 2. This length is the length in the direction of the cell pitch p1A (e.g., X-axis direction) in the embodiment 2, and a value thereof is preferably equal to or larger than the thickness of the gate insulating film 21 (e.g., 100 nm or more) and 0.6 μm or less. This can further prevent the mixing of hydrogen from the front surface 10a side of the GaN substrate 10 through the source region 23.

Also in the embodiment 2, the gate electrode 22 is not limited to the three-layer structure of the first conductive layer 221A, the hydrogen blocking layer 222, and the second conductive layer 221B as with the embodiment 1. The stacking order and the number of stacked layers of the conductive layer 221 and the hydrogen blocking layer 222 constituting the gate electrode 22 may be optionally set, and, for example, may be a two-layer structure as illustrated in FIGS. 3A and 3B, may be a four-layer structure as illustrated in FIGS. 4A and 4B, or may be a five or more-layer structure although not illustrated. The same applies to an embodiment 3 described next.

### Embodiment 3

The above-described embodiment 2 shows the aspect in which the gate electrode 22 is extended from within the trench h12 onto the peripheral region of the trench h12. However, a trench gate vertical MOSFET according to this embodiment is not limited thereto. The gate electrode 22 is provided only in the trench h12 and does not have to be extended onto the peripheral region of the trench h12.

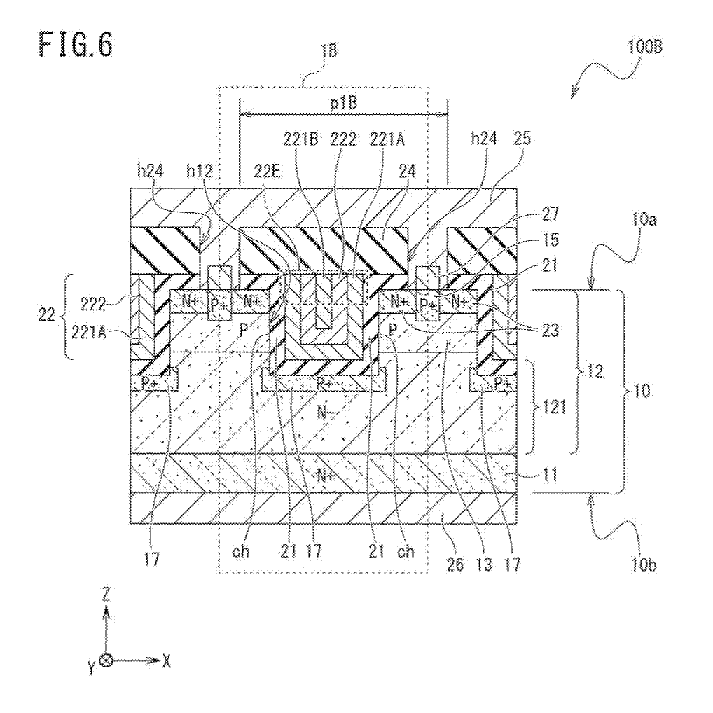

FIG. 6 is a cross-sectional view illustrating a configuration example of a GaN semiconductor device 100B according to this embodiment 3. As illustrated in FIG. 6, the GaN semiconductor device 100B includes the GaN substrate 10 and a plurality of vertical MOSFETs 1B provided on the GaN substrate 10. The vertical MOSFET 1B has a trench gate structure. The gate electrode 22 has a stacked-layer structure containing the first conductive layer 221A, the hydrogen blocking layer 222, and the second conductive layer 221B. In the vertical MOSFET 1B, the gate electrode 22 is provided only in the trench h12 and is not extended onto the peripheral region of the trench h12. The end part 22E of the gate electrode 22 is arranged at a position overlapping the source region 23 through the gate insulating film 21 in a direction parallel to the front surface 10a of the GaN substrate 10 (e.g., X-axis direction). Even such an aspect, the reduction in Vth can be suppressed as with the embodiment 2. A cell pitch p1B of the vertical MOSFETs 1B is not particularly limited, and is 3 μm or more and 8 μm or less as one example and is 4 μm as one example.

### Embodiment 4

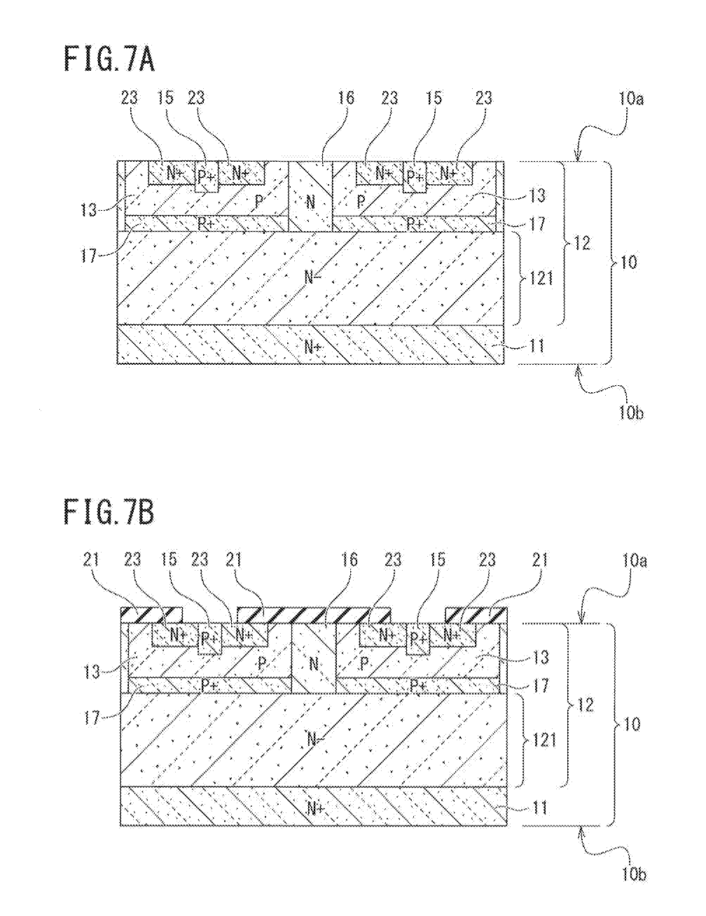

Next, a method for manufacturing the vertical MOSFET 1 illustrated in FIG. 1 is described as this embodiment 4. FIGS. 7A to 9B are cross-sectional views illustrating the method for manufacturing the vertical MOSFET 1 according to this embodiment 4 in the order of steps. The vertical MOSFETs are manufactured by various types of devices, such as a film formation device, an exposure device, an ion implantation device, an etching device, and a heat treatment device. Hereinafter, these devices are collectively referred to as a manufacturing device.

As illustrated in FIG. 7A, the manufacturing device epitaxially grows the N⁻-type GaN layer 12 on the N⁺-type GaN single-crystal substrate 11. Next, the manufacturing device sequentially ion-implants acceptor elements (e.g., Mg) and donor elements (e.g., O, Si) into the GaN layer 12 using a photolithography technology and an ion implantation technology to form the P⁺-type shield regions 17, the P-type well regions 13, the N-type JFET region 16, the N⁺-type source regions 23, and the P⁺-type contact regions 15 in this order. The order of forming these regions is only one example, and the manufacturing method of this embodiment is not limited thereto.

Next, the manufacturing device applies heat treatment to the GaN substrate 10 to activate the acceptor elements (e.g., Mg) and the donor elements (e.g., O, Si) that were ion-implanted. For example, a protective film is formed on the front surface 10a of the GaN substrate 10, heat treatment is applied, and thereafter the protective film is removed. As one example, a 100 nm thick aluminum nitride (AlN) film is used as the protective film. As the conditions of the heat treatment, the maximum temperature is 1300°C, the atmosphere is N₂, and the treatment time at the maximum temperature is 10 minutes. For the removal of the protective film, TMAH (tetramethylammonium hydroxide) is used.

Next, the manufacturing device forms the gate insulating films 21 on the front surface 10a of the GaN substrate 10 as illustrated in FIG. 7B. For example, the manufacturing device form 100 nm thick SiO₂ films by a PDCVD method as the gate insulating films 21. Although not illustrated, the manufacturing device may also form a field insulating film in a peripheral part of the GaN substrate 10 before the formation of the gate insulating films 21. After the formation of the gate insulating films 21, the manufacturing device may apply heat treatment to the GaN substrate 10 to densify the gate insulating films 21.

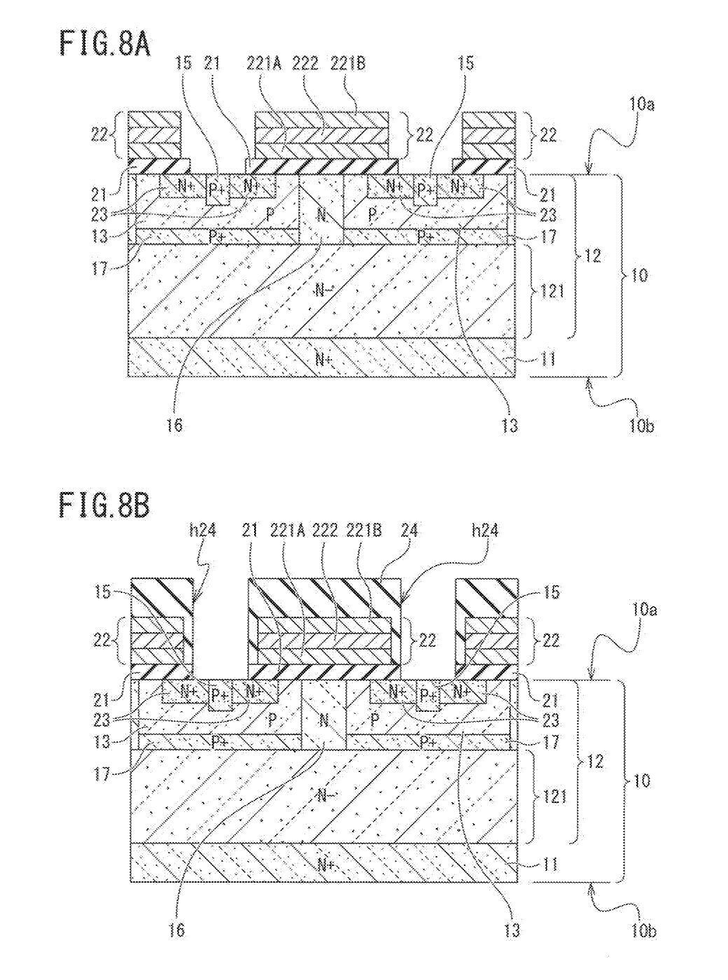

Next, the manufacturing device forms a film of a stacked-layer structure (i.e., stacked-layer film) constituting the gate electrodes 22 on the gate insulating films 21 as illustrated in FIG. 8A. The first conductive layer 221A, the hydrogen blocking layer 222, and the second conductive layer 221B are formed in this order by a sputtering method, for example. As one example, TiN is formed into a 50 nm thick film as the first conductive layer 221A, Ti is formed into a 100 nm thick film as the hydrogen blocking layer 222, and TiN is formed into a 50 nm thick film as the second conductive layer 221B. The first conductive layer 221A and the second conductive layer 221B may be polysilicon doped with impurities (doped-poly Si). The doped-poly Si is formed by a CVD method. Thereafter, the manufacturing device patterns the film of the stacked-layer structure using a photolithography technology and a dry etching technology to form the gate electrodes 22.

Next, the manufacturing device forms the interlayer insulating film 24 on the front surface 10a side of the GaN substrate 10 as illustrated in FIG. 8B. For example, as the interlayer insulating film 24, SiO₂ is formed into a 1 µm thick film by a plasma CVD method using TEOS as a raw material. Next, the manufacturing device applies heat treatment to the interlayer insulating film 24 for densification. As the conditions of the heat treatment, the maximum temperature is 600°C, the atmosphere is N₂, and the treatment time at the maximum temperature is 30 minutes. Next, the manufacturing device patterns the interlayer insulating film 24 using a photolithography technology and a dry etching technology to form the contact hole h24.

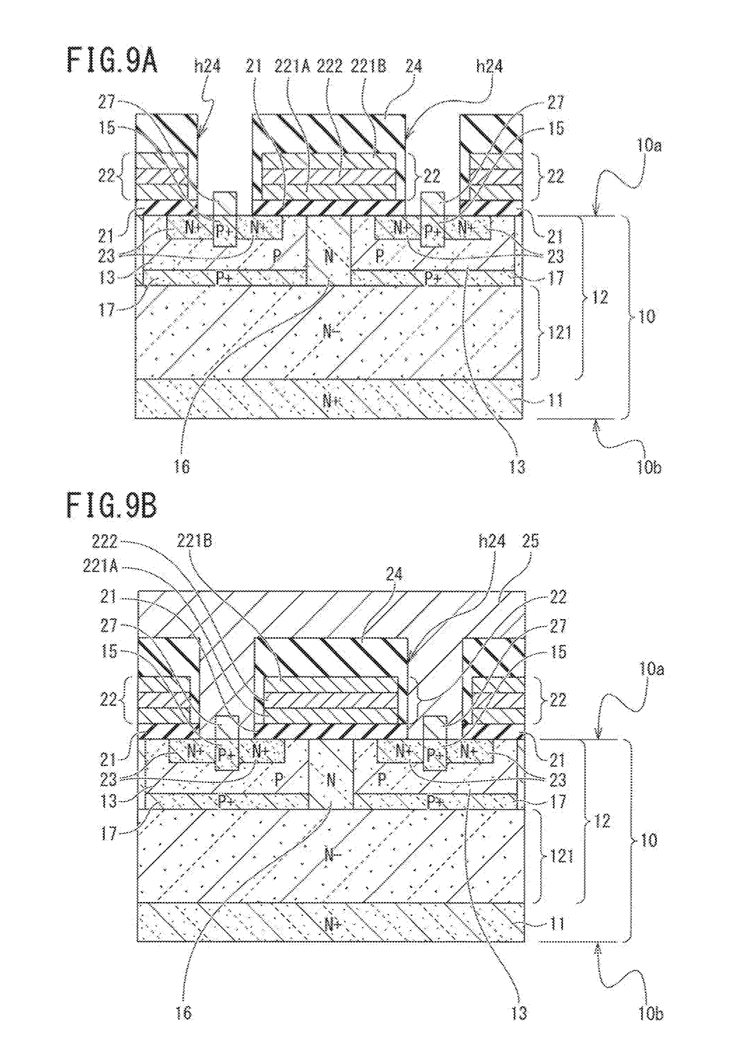

Next, the manufacturing device forms the contact electrodes 27 on the P⁺-type contact regions 15 positioned at the bottom surface of the contact hole h24 as illustrated in FIG. 9A. The contact electrode 27 is, for example, 50 nm thick Ni. The patterning of the contact electrodes 27 is performed by wet etching.

Next, the manufacturing device forms the source electrode 25 on the front surface 10a side of the GaN substrate 10, and brings the source electrode 25 into contact with the N⁺-type source regions 23 and the contact electrodes 27 as illustrated in FIG. 9B. For example, Ti is formed into a 100 nm thick film, Al is formed into a 5000 nm thick film, and these films are patterned by wet etching to form the source electrode 25.

Next, the manufacturing device forms the drain electrode 26 (see FIG. 1) on the rear surface 10b side of the GaN substrate 10, and brings the drain electrode 26 into contact with the N⁺-type GaN single crystal substrate 11. For example, Ti is formed into a 100 nm thick film, and Al is formed into a 200 nm thick film to form the drain electrode 26 (see FIG. 1). Thereafter, the manufacturing device performs sintering (e.g., heat treatment under an N₂ atmosphere). Through the steps above, the planar gate vertical MOSFET 1 illustrated in FIG. 1 is completed.

### Other embodiments

As described above, although the present disclosure is described by the embodiments and the modifications thereof, the discussion and the drawings forming part of this disclosure should not be understood as limiting the present disclosure. Various alternative embodiments and modifications will be apparent to those skilled in the art from this disclosure. For example, the contact electrode 27 may be omitted in the vertical MOSFET 1 illustrated in FIG. 1. In place of the contact electrode 27, the source electrode 25 may be connected to the P⁺-type contact region 15 in an ohmic manner. The "compound semiconductor substrate" of the present disclosure may be a silicon carbide (SiC) substrate instead of the GaN substrate. The "compound semiconductor device" of the present disclosure may be a SiC semiconductor device instead of the GaN semiconductor device. Thus, it is a matter of course that the present technology includes various embodiments and the like that are not described herein. At least one of various omissions, substitutions, and alternations of the constituent components can be performed without departing from the gist of the embodiments and the modifications described above. Further, the effects described in this specification are merely examples and are not limited, and other effects may also be involved.

The present disclosure can also take the following configurations.
1. A compound semiconductor device including:
   a compound semiconductor substrate; and
   a vertical MOSFET provided on the compound semiconductor substrate, in which
   the vertical MOSFET has
   a gate insulating film provided on a first surface of the compound semiconductor substrate,
   a gate electrode provided on the first surface of the compound semiconductor substrate through the gate insulating film,
   an interlayer insulating film provided on the first surface of the compound semiconductor substrate and covering the gate electrode, and
   an N-type source region provided in the compound semiconductor substrate,
   the gate electrode has a stacked-layer structure containing a conductive layer and a hydrogen blocking layer containing a conductive material different from a conductive material of the conductive layer and blocking the diffusion of hydrogen, and
   the gate electrode has an end part overlapping the source region through the gate insulating film.

2. The compound semiconductor device according to (1) above, in which the conductive layer comprises
a first conductive layer interposed between the gate insulating film and the hydrogen blocking layer.

3. The compound semiconductor device according to (1) or (2) above, in which the conductive layer comprises
a second conductive layer interposed between the hydrogen blocking layer and the interlayer insulating film.

4. The compound semiconductor device according to any one of (1) to (3) above, in which t
he hydrogen blocking layer comprises a first hydrogen blocking layer and a second hydrogen blocking layer, and
the conductive layer is interposed between the first hydrogen blocking layer and the second hydrogen blocking layer.

5. The compound semiconductor device according to any one of (1) to (4) above, in which the hydrogen blocking layer has a thickness per layer of 10 nm or more and 200 nm or less.

6. The compound semiconductor device according to any one of (1) to (5) above, in which the conductive layer has a thickness per layer of 10 nm or more and 200 nm or less.

7. The compound semiconductor device according to any one of (1) to (6) above, in which
the vertical MOSFET has a planar gate structure, and
the length in a gate length direction of a region where the end part of the gate electrode and the source region overlap each other is equal to or larger than the thickness of the gate insulating film and 0.6 μm or less.

8. The compound semiconductor device according to any one of (1) to (7) above, in which the width of the sidewall covering the side surface of the gate electrode in the interlayer insulating film is equal to or larger than the thickness of the gate insulating film and 0.5 μm or less.

9. The compound semiconductor device according to any one of (1) to (8) above, in which the hydrogen blocking layer contains any one of simple metals of titanium (Ti), zirconium (Zr), palladium (Pd), and magnesium (Mg) or a Ti compound containing titanium (Ti) as the main component.

10. The compound semiconductor device according to any one of (1) to (9) above, in which the gate insulating film contains one or more layers of silicon oxide (SiO₂), aluminum oxide (Al₂O₃), aluminum silicate (AlSiO₂), zirconium oxide (ZrO₂), and hafnium oxide (HfO₂).

11. The compound semiconductor device according to any one of (1) to (10) above, in which the conductive layer contains one or more layers of nickel (Ni), aluminum (Al), tungsten (W), titanium nitride (TiN), or polysilicon doped with impurities (doped-poly Si).

12. A method for manufacturing a compound semiconductor device for forming a vertical MOSFET on a compound semiconductor substrate including:
forming an N-type source region in the compound semiconductor substrate;
forming a gate insulating film on a first surface of the compound semiconductor substrate;
forming a gate electrode on the first surface of the compound semiconductor substrate through the gate insulating film; and
forming an interlayer insulating film on the first surface of the compound semiconductor substrate and covering the gate electrode, in which
in the forming the gate electrode,
a conductive layer and a hydrogen blocking layer containing a conductive material different from a conductive material of the conductive layer and blocking the diffusion of hydrogen are stacked to form a film formed of a stacked-layer structure, and
the film of the stacked-layer structure is patterned such that an end part of the gate electrode overlaps the source region through the gate insulating film.

1. A compound semiconductor device comprising:
a compound semiconductor substrate; and
a vertical MOSFET provided on the compound semiconductor substrate, wherein
the vertical MOSFET has
a gate insulating film provided on a first surface of the compound semiconductor substrate,
a gate electrode provided on the first surface of the compound semiconductor substrate through the gate insulating film,
an interlayer insulating film provided on the first surface of the compound semiconductor substrate and covering the gate electrode, and
an N-type source region provided in the compound semiconductor substrate,
the gate electrode has a stacked-layer structure containing a conductive layer and a hydrogen blocking layer containing a conductive material different from a conductive material of the conductive layer and configured to block diffusion of hydrogen, and
the gate electrode has an end part overlapping the source region through the gate insulating film.

2. The compound semiconductor device according to claim 1, wherein the conductive layer comprises
a first conductive layer interposed between the gate insulating film and the hydrogen blocking layer.

3. The compound semiconductor device according to claim 1, wherein the conductive layer comprises
a second conductive layer interposed between the hydrogen blocking layer and the interlayer insulating film.

4. The compound semiconductor device according to claim 1, wherein
the hydrogen blocking layer comprises a first hydrogen blocking layer and a second hydrogen blocking layer, and
the conductive layer is interposed between the first hydrogen blocking layer and the second hydrogen blocking layer.

5. The compound semiconductor device according to claim 1, wherein the hydrogen blocking layer has a thickness per layer of 10 nm or more and 200 nm or less.

6. The compound semiconductor device according to claim 1, wherein the conductive layer has a thickness per layer of 10 nm or more and 200 nm or less.

7. The compound semiconductor device according to claim 1, wherein
the vertical MOSFET has a planar gate structure, and
a length in a gate length direction of a region where the end part of the gate electrode and the source region overlap each other is equal to or larger than a thickness of the gate insulating film and 0.6 μm or less.

8. The compound semiconductor device according to claim 1, wherein a width of a sidewall covering a side surface of the gate electrode in the interlayer insulating film is equal to or larger than a thickness of the gate insulating film and 0.5 μm or less.

9. The compound semiconductor device according to claim 1, wherein the hydrogen blocking layer contains any one of simple metals of titanium (Ti), zirconium (Zr), palladium (Pd), and magnesium (Mg) or a Ti compound containing titanium (Ti) as a main component.

10. The compound semiconductor device according to claim 1, wherein the gate insulating film contains one or more layers of silicon oxide (SiO₂), aluminum oxide (Al₂O₃), aluminum silicate (AlSiO₂), zirconium oxide (ZrO₂), and hafnium oxide (HfO₂).

11. The compound semiconductor device according to claim 1, wherein the conductive layer contains one or more layers of nickel (Ni), aluminum (Al), tungsten (W), titanium nitride (TiN), or polysilicon doped with impurities (doped-poly Si).

12. A method for manufacturing a compound semiconductor device for forming a vertical MOSFET on a compound semiconductor substrate comprising:
forming an N-type source region in the compound semiconductor substrate;
forming a gate insulating film on a first surface of the compound semiconductor substrate;
forming a gate electrode on the first surface of the compound semiconductor substrate through the gate insulating film; and
forming an interlayer insulating film on the first surface of the compound semiconductor substrate and covering the gate electrode, wherein
in the forming the gate electrode,
a conductive layer and a hydrogen blocking layer containing a conductive material different from a conductive material of the conductive layer and configured to block diffusion of hydrogen are stacked to form a film formed of a stacked-layer structure, and
the film of the stacked-layer structure is patterned such that an end part of the gate electrode overlaps the source region through the gate insulating film.
